(19) United States
(12) Patent Application Publication
(10) Pub. No.: US 2022/0038077 A1
(43) Pub. Date: Feb. 3, 2022

(54) BULK-ACOUSTIC WAVE RESONATOR AND METHOD FOR FABRICATING A BULK-ACOUSTIC WAVE RESONATOR

(71) Applicant: Samsung Electro-Mechanics Co., Ltd., Suwon-si (KR)

(72) Inventors: Tae Kyung LEE, Suwon-si (KR); Yong Suk KIM, Suwon-si (KR); Sang Kee YOON, Suwon-si (KR); Jin Suk SON, Suwon-si (KR); Ran Hee SHIN, Suwon-si (KR)

(73) Assignee: Samsung Electro-Mechanics Co., Ltd., Suwon-si (KR)

(21) Appl. No.: 17/094,019

(22) Filed: Nov. 10, 2020

(30) Foreign Application Priority Data
Jul. 28, 2020 (KR) 10-2020-0093988

(51) Int. Cl. H03H 9/17; H03H 9/02; H03H 9/13; H03H 3/02

(52) U.S. Cl. CPC H03H 9/174; H03H 3/02; H03H 9/131; H03H 9/02015

(57) ABSTRACT

A bulk-acoustic wave resonator includes a resonator having a central portion in which a first electrode, a piezoelectric layer, and a second electrode are sequentially stacked on a substrate, and an extension portion disposed along a periphery of the central portion and in which an insertion layer is disposed below the piezoelectric layer, wherein the insertion layer includes a SiO₂ thin film injected with fluorine (F).

### CROSS-REFERENCE TO RELATED APPLICATIONS

This application claims the benefit under 35 USC 119(a) of Korean Patent Application No. 10-2020-0093988 filed on Jul. 28, 2020, in the Korean Intellectual Property Office, the entire disclosure of which is incorporated herein by reference for all purposes.

### BACKGROUND

### 1. Field

The present disclosure relates to a bulk-acoustic wave resonator and a method for manufacturing a bulk-acoustic wave resonator.

### 2. Description of the Background

In accordance with the trend for the miniaturization of wireless communication devices, the miniaturization of high frequency component technology has been actively demanded. For example, a bulk-acoustic wave (BAW) type filter using semiconductor thin film wafer manufacturing technology may be used.

A bulk-acoustic resonator (BAW) is formed when a thin film type element, causing resonance by depositing a piezoelectric dielectric material on a silicon wafer, a semiconductor substrate, and using the piezoelectric characteristics thereof, is implemented as a filter.

Recently, technological interest in 5G communication is increasing, and the development of technologies that can be implemented in candidate bands is being actively performed.

However, in the case of 5G communications using a Sub 6 GHz (4 to 6 GHz) frequency band, since the bandwidth is increased and the communication distance is shortened, the strength or power of the signal of the bulk-acoustic wave resonator may be increased. In addition, as the frequency increases, losses occurring in the piezoelectric layer or the resonator may be increased.

Therefore, a bulk-acoustic wave resonator capable of minimizing the energy leakage from the resonator is required.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator includes a resonator having a central portion in which a first electrode, a piezoelectric layer, and a second electrode are sequentially stacked on a substrate, and an extension portion disposed along a periphery of the central portion and in which an insertion layer is disposed below the piezoelectric layer, wherein the insertion layer may be formed of a SiO₂ thin film injected with fluorine (F).

The fluorine (F) contained in the insertion layer may be present in a range of 0.5 at % or more and 15 at % or less.

The piezoelectric layer may include aluminum nitride (AlN) or scandium (Sc) doped aluminum nitride.

The first electrode may include molybdenum (Mo).

The insertion layer may have an inclined surface whose thickness increases as a distance from the central portion increases, and the piezoelectric layer may have an inclined portion disposed on the inclined surface.

In a cross-section of the resonator, an end of the second electrode may be disposed at a boundary between the central portion and the extension portion, or disposed on the inclined portion.

The piezoelectric layer may include a piezoelectric portion disposed in the central portion, and an extension portion extending outwardly of the inclined portion, and at least a portion of the second electrode may be disposed on the extension portion of the piezoelectric layer.

In another general aspect, a method for manufacturing a bulk-acoustic wave resonator includes forming a resonator having a central portion in which a first electrode, a piezoelectric layer, and a second electrode are sequentially stacked on a substrate, and an extension portion in which an insertion layer is disposed along a periphery of the central portion, wherein the insertion layer is disposed below the first electrode or between the first electrode and the piezoelectric layer and is formed of a SiO₂ thin film injected with fluorine (F).

The piezoelectric layer may be formed of aluminum nitride (AlN) or scandium (Sc) doped aluminum nitride.

The insertion layer may be formed by mixing SiH₄ gas with any one of CF₄, NF₃, SiF₆, CHF₃, C₄F₈, and C₂F₆ gas.

The insertion layer may be formed by a chemical vapor deposition (CVD) method, and according to Equation 1, (Equation 1) SiH₄+O₂+CF₄→F—SiO₂+2H₂+CO₂, where F—SiO₂ is SiO₂ thin film injected with fluorine (F).

The piezoelectric layer and the second electrode may be at least partially raised by the insertion layer.

In a cross-section of the resonator, at least a portion of an end of the second electrode may be disposed to overlap the insertion layer.

In a cross-section of the resonator, the end of the second electrode may be disposed in the extension portion.

Other features and aspects will be apparent from the following detailed description, the drawings, and the claims.

### BRIEF DESCRIPTION OF DRAWINGS

FIG. 1 is a plan view of a bulk-acoustic wave resonator according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ in FIG. 1.

FIGS. 5 and 6 are diagrams illustrating dimensions of a photoresist applied on an insertion layer.

FIG. 7 is a diagram illustrating a result of measuring surface roughness of the insertion layer.

FIG. 8 is a diagram illustrating density, a modulus of elasticity, and a reflective characteristic of an insertion layer according to a fluorine content.

FIG. 9 is a graph illustrating the change in reflective characteristics of FIG. 8.

FIG. 10 is a cross-sectional view schematically illustrating a bulk-acoustic wave resonator according to another embodiment of the present disclosure.

FIG. 11 is a cross-sectional view schematically illustrating a bulk-acoustic wave resonator according to another embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may be also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure is to provide a bulk-acoustic wave resonator capable of minimizing leakage of energy and a method for manufacturing the same.

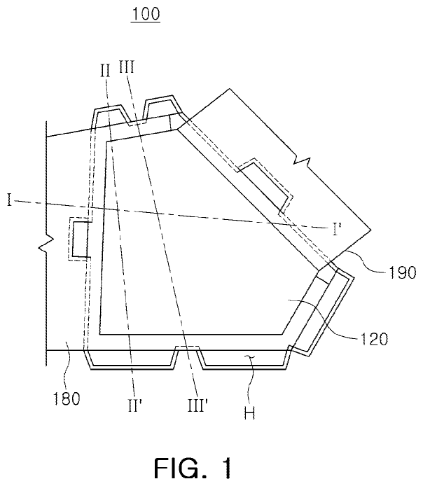

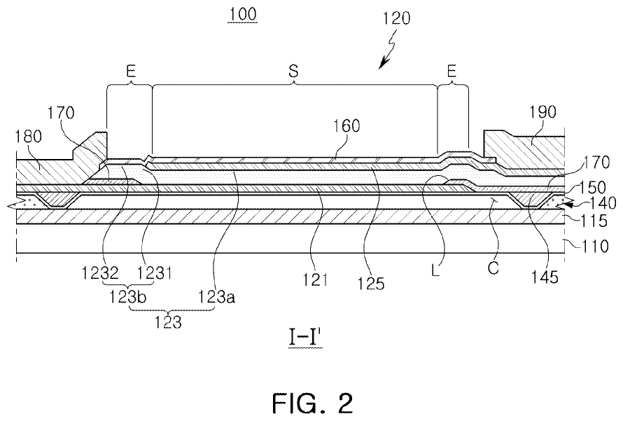

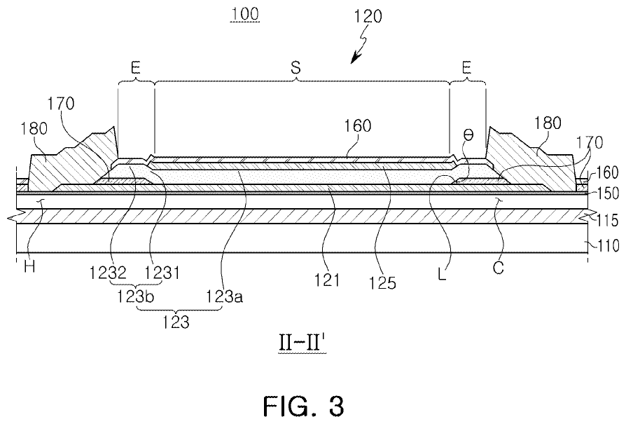

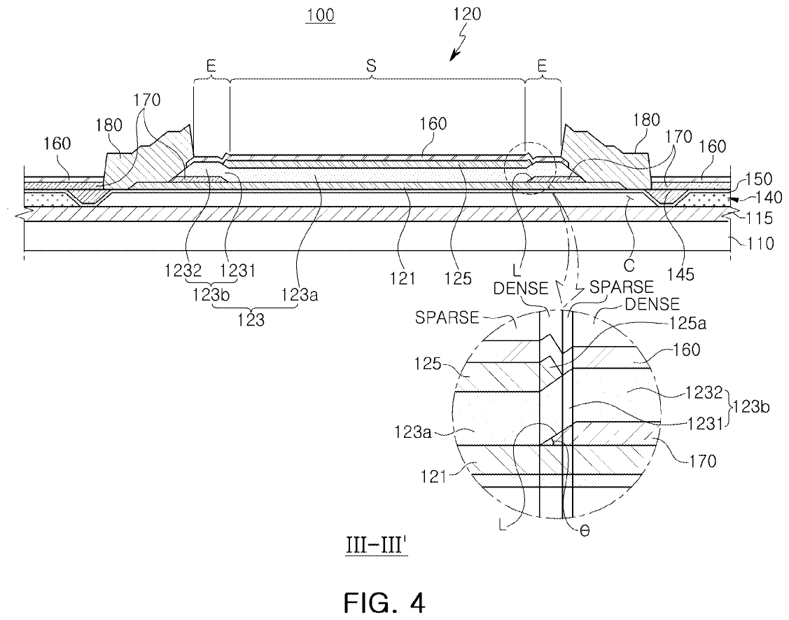

FIG. 1 is a plan view of an acoustic wave resonator according to an embodiment of the present disclosure, FIG. 2 is a cross-sectional view taken along line I-I′ of FIG. 1, FIG. 3 is a cross-sectional view taken along line II-II′ of FIG. 1, and FIG. 4 is a cross-sectional view taken along line III-III′ of FIG. 1.

Referring to FIGS. 1 to 4, an acoustic wave resonator 100 according to an embodiment of the present disclosure may be a bulk acoustic wave (BAW) resonator, and may include a substrate 110, a sacrificial layer 140, a resonator 120, and an insertion layer 170.

The substrate 110 may be a silicon substrate. For example, a silicon wafer may be used as the substrate 110, or a silicon on insulator (SOI) type substrate may be used.

An insulating layer 115 may be provided on an upper surface of the substrate 110 to electrically isolate the substrate 110 and the resonator 120. In addition, the insulating layer 115 prevents the substrate 110 from being etched by an etching gas when a cavity C is formed in a manufacturing process of the acoustic-wave resonator.

In this case, the insulating layer 115 may be formed of at least one of silicon dioxide (SiO₂), silicon nitride (Si₃N₄), aluminum oxide (Al₂O₃), and aluminum nitride (AlN), and may be formed through any one process of chemical vapor deposition, RF magnetron sputtering, and evaporation.

The sacrificial layer 140 is formed on the insulating layer 115, and the cavity C and an etch stop portion 145 are disposed in the sacrificial layer 140.

The cavity C is formed as an empty space, and may be formed by removing a portion of the sacrificial layer 140.

As the cavity C is formed in the sacrificial layer 140, the resonator 120 formed above the sacrificial layer 140 may be formed to be entirely flat.

The etch stop portion 145 is disposed along a boundary of the cavity C. The etch stop portion 145 is provided to prevent etching from being performed beyond a cavity region in a process of forming the cavity C.

A membrane layer 150 is formed on the sacrificial layer 140, and forms an upper surface of the cavity C. Therefore, the membrane layer 150 is also formed of a material that is not easily removed in the process of forming the cavity C.

For example, when a halide-based etching gas such as fluorine (F), chlorine (Cl), or the like is used to remove a portion (e.g., a cavity region) of the sacrificial layer 140, the membrane layer 150 may be made of a material having low reactivity with the etching gas. In this case, the membrane layer 150 may include at least one of silicon dioxide (SiO₂) and silicon nitride (Si₃N₄).

In addition, the membrane layer 150 may be made of a dielectric layer containing at least one material of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing at least one material of aluminum (Al), nickel (Ni), chromium (Cr), platinum (Pt), gallium (Ga), and hafnium (Hf). However, a configuration of the present disclosure is not limited thereto.

The resonator 120 includes a first electrode 121, a piezoelectric layer 123, and a second electrode 125. The resonator 120 is configured such that the first electrode 121, the piezoelectric layer 123, and the second electrode 125 are stacked in order from a bottom. Therefore, the piezoelectric layer 123 in the resonator 120 is disposed between the first electrode 121 and the second electrode 125.

Since the resonator 120 is formed on the membrane layer 150, the membrane layer 150, the first electrode 121, the piezoelectric layer 123, and the second electrode 125 are sequentially stacked on the substrate 110, to form the resonator 120.

The resonator 120 may resonate the piezoelectric layer 123 according to signals applied to the first electrode 121 and the second electrode 125 to generate a resonant frequency and an anti-resonant frequency.

The resonator 120 may be divided into a central portion S in which the first electrode 121, the piezoelectric layer 123, and the second electrode 125 are stacked to be substantially flat, and an extension portion E in which the insertion layer 170 is interposed between the first electrode 121 and the piezoelectric layer 123.

The central portion S is a region disposed in a center of the resonator 120, and the extension portion E is a region disposed along a periphery of the central portion S. Therefore, the extension portion E is a region extended from the central portion S externally, and refers to a region formed to have a continuous annular shape along the periphery of the central portion S. However, if necessary, the extension portion E may be configured to have a discontinuous annular shape, in which some regions are disconnected.

Accordingly, as shown in FIG. 2, in the cross-section of the resonator 120 cut so as to cross the central portion S, the extension portion E is disposed on both ends of the central portion S, respectively. An insertion layer 170 is disposed on both sides of the central portion S in the extension portion E disposed on both ends of the central portion S.

The insertion layer 170 has an inclined surface L of which a thickness becomes greater as a distance from the central portion S increases.

In the extension portion E, the piezoelectric layer 123 and the second electrode 125 are disposed on the insertion layer 170. Therefore, the piezoelectric layer 123 and the second electrode 125 located in the extension portion E have an inclined surface along the shape of the insertion layer 170.

In the present embodiment, the extension portion E is included in the resonator 120, and accordingly, resonance may also occur in the extension portion E. However, the present disclosure is not limited thereto, and resonance may not occur in the extension portion E depending on the structure of the extension portion E, but resonance may occur only in the central portion S.

The first electrode 121 and the second electrode 125 may be formed of a conductor, for example, may be formed of gold, molybdenum, ruthenium, iridium, aluminum, platinum, titanium, tungsten, palladium, tantalum, chromium, nickel, or a metal containing at least one thereof, but is not limited thereto.

In the resonator 120, the first electrode 121 is formed to have a larger area than the second electrode 125, and a first metal layer 180 is disposed along a periphery of the first electrode 121 on the first electrode 121. Therefore, the first metal layer 180 may be disposed to be spaced apart from the second electrode 125 by a predetermined distance, and may be disposed in a form surrounding the resonator 120.

Since the first electrode 121 is disposed on the membrane layer 150, the first electrode 121 is formed to be entirely flat. On the other hand, since the second electrode 125 is disposed on the piezoelectric layer 123, curving may be formed corresponding to the shape of the piezoelectric layer 123.

The first electrode 121 may be used as any one of an input electrode and an output electrode for inputting and outputting an electrical signal such as a radio frequency (RF) signal.

The second electrode 125 is entirely disposed in the central portion S, and partially disposed in the extension portion E. Accordingly, the second electrode 125 may be divided into a portion disposed on a piezoelectric portion 123a of the piezoelectric layer 123 to be described later, and a portion disposed on a curved portion 123b of the piezoelectric layer 123.

For example, in the present embodiment, the second electrode 125 is disposed to cover an entirety of the piezoelectric portion 123a and a portion of an inclined portion 1231 of the piezoelectric layer 123. Accordingly, the second electrode (125a in FIG. 4) disposed in the extension portion E is formed to have a smaller area than an inclined surface of the inclined portion 1231, and the second electrode 125 in the resonator 120 is formed to have a smaller area than the piezoelectric layer 123.

Accordingly, as shown in FIG. 2, in a cross-section of the resonator 120 cut so as to cross the central portion S, an end of the second electrode 125 is disposed in the extension portion E. In addition, at least a portion of the end of the second electrode 125 disposed in the extension portion E is disposed to overlap the insertion layer 170. Here, ‘overlap’ means that when the second electrode 125 is projected on a plane on which the insertion layer 170 is disposed, a shape of the second electrode 125 projected on the plane overlaps the insertion layer 170.

The second electrode 125 may be used as any one of an input electrode and an output electrode for inputting and outputting an electrical signal such as a radio frequency (RF) signal, or the like. That is, when the first electrode 121 is used as the input electrode, the second electrode 125 may be used as the output electrode, and when the first electrode 121 is used as the output electrode, the second electrode 125 may be used as the input electrode.

As illustrated in FIG. 4, when the end of the second electrode 125 is positioned on the inclined portion 1231 of the piezoelectric layer 123 to be described later, since a local structure of an acoustic impedance of the resonator 120 is formed in a sparse/dense/sparse/dense structure from the central portion S, a reflective interface reflecting a lateral wave inwardly of the resonator 120 is increased. Therefore, since most lateral waves cannot flow outwardly of the resonator 120, and are reflected and then flow to an interior of the resonator 120, the performance of the acoustic resonator may be improved.

The piezoelectric layer 123 is a portion converting electrical energy into mechanical energy in a form of elastic waves through a piezoelectric effect, and is formed on the first electrode 121 and the insertion layer 170 to be described later.

As a material of the piezoelectric layer 123, zinc oxide (ZnO), aluminum nitride (AlN), doped aluminum nitride, lead zirconate titanate, quartz, and the like can be selectively used. In the case of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

In order to improve piezoelectric properties, when a content of elements doped with aluminum nitride (AlN) is less than 0.1 at %, a piezoelectric property higher than that of aluminum nitride (AlN) cannot be realized. When the content of the elements exceeds 30 at %, it is difficult to fabricate and control the composition for deposition, such that uneven crystalline phases may be formed.

Therefore, in the present embodiment, the content of elements doped with aluminum nitride (AlN) may be in a range of 0.1 to 30 at %.

In the present embodiment, the piezoelectric layer is doped with scandium (Sc) in aluminum nitride (AlN). In this case, a piezoelectric constant may be increased to increase Kₜ² of the acoustic resonator.

The piezoelectric layer 123 according to the present embodiment includes a piezoelectric portion 123a disposed in the central portion S and a curved portion 123b disposed in the extension portion E.

The piezoelectric portion 123a is a portion directly stacked on the upper surface of the first electrode 121. Therefore, the piezoelectric portion 123a is interposed between the first electrode 121 and the second electrode 125 to be formed as a flat shape, together with the first electrode 121 and the second electrode 125.

The curved portion 123b may be understood as a region extending from the piezoelectric portion 123a to the outside and positioned in the extension portion E.

The curved portion 123b is disposed on the insertion layer 170 to be described later, and is formed in a shape in which the upper surface thereof is raised along the shape of the insertion layer 170. Accordingly, the piezoelectric layer 123 is curved at a boundary between the piezoelectric portion 123a and the curved portion 123b, and the curved portion 123b is raised corresponding to the thickness and shape of the insertion layer 170. The second electrode 125 disposed on the curved portion 123b may also be partially raised along the shape of the insertion layer 170. The curved portion 123b may be divided into an inclined portion 1231 and an extension portion 1232.

The inclined portion 1231 refers to a portion formed to be inclined along an inclined surface L of the insertion layer 170 to be described later. The extension portion 1232 refers to a portion extending from the inclined portion 1231 to the outside.

The inclined portion 1231 is formed parallel to the inclined surface L of the insertion layer 170, and an inclination angle of the inclined portion 1231 may be formed to be the same as an inclination angle of the inclined surface L of the insertion layer 170.

The insertion layer 170 is disposed along a surface formed by the membrane layer 150, the first electrode 121, and the etch stop portion 145. Therefore, the insertion layer 170 is partially disposed in the resonator 120, and is disposed between the first electrode 121 and the piezoelectric layer 123.

The insertion layer 170 is disposed around the central portion S to support the curved portion 123b of the piezoelectric layer 123. Accordingly, the curved portion 123b of the piezoelectric layer 123 may be divided into an inclined portion 1231 and an extension portion 1232 according to the shape of the insertion layer 170.

In the present embodiment, the insertion layer 170 is disposed in a region except for the central portion S. For example, the insertion layer 170 may be disposed on the substrate 110 in an entire region except for the central portion S, or in some regions.

The insertion layer 170 is formed to have a thickness becoming greater as a distance from the central portion S increases. Thereby, the insertion layer 170 is formed of an inclined surface L having a constant inclination angle θ of the side surface disposed adjacent to the central portion S.

When the inclination angle θ of the side surface of the insertion layer 170 is formed to be smaller than 5°, in order to manufacture it, since the thickness of the insertion layer 170 should be formed to be very thin or an area of the inclined surface L should be formed to be excessively large, it is practically difficult to be implemented.

In addition, when the inclination angle θ of the side surface of the insertion layer 170 is formed to be greater than 70°, the inclination angle of the piezoelectric layer 123 or the second electrode 125 stacked on the insertion layer 170 is also formed to be greater than 70°. In this case, since the piezoelectric layer 123 or the second electrode 125 stacked on the inclined surface L is excessively curved, cracks may be generated in the curved portion.

Therefore, in the present embodiment, the inclination angle θ of the inclined surface L is formed in a range of 5° or more and 70° or less.

In the present embodiment, the inclined portion 1231 of the piezoelectric layer 123 is formed along the inclined surface L of the insertion layer 170, and thus is formed at the same inclination angle as the inclined surface L of the insertion layer 170. Therefore, the inclination angle of the inclined portion 1231 is also formed in the range of 5° or more and 70° or less, similarly to the inclined surface L of the insertion layer 170. The configuration may also be equally applied to the second electrode 125 stacked on the inclined surface L of the insertion layer 170.

The insertion layer 170 may be formed of a thin film in which a small amount of fluorine (F) is injected into the SiO₂ thin film.

When an insertion layer 170 is formed of silicon dioxide (SiO₂), a fluorine-injected SiO₂ thin film (hereinafter, a F—SiO₂ thin film) may be formed by mixing any one of CF₄, NF₃, SiF₆, CHF₃, C₄F₈, and C₂F₆ gas in SiH₄ gas in an appropriate ratio.

The resonator 120 is disposed to be spaced apart from the substrate 110 through a cavity C formed as an empty space.

The cavity C may be formed by removing a portion of a sacrificial layer 140 by supplying an etching gas (or an etching solution) to an inlet hole (H in FIG. 1) in a process of manufacturing an acoustic resonator.

A protective layer 160 is disposed along the surface of the acoustic resonator 100 to protect the acoustic resonator 100 from the outside. The protective layer 160 may be disposed along a surface formed by the second electrode 125 and the curved portion 123b of the piezoelectric layer 123.

The first electrode 121 and the second electrode 125 may extend outside the resonator 120. In addition, a first metal layer 180 and a second metal layer 190 may be disposed on the upper surface of the extended portion, respectively.

The first metal layer 180 and the second metal layer 190 may be made of any material among gold (Au), a gold-tin (Au—Sn) alloy, copper (Cu), a copper-tin (Cu—Sn) alloy, aluminum (Al), an aluminum alloy, or combinations thereof. Here, the aluminum alloy may be an aluminum-germanium (Al—Ge) alloy or an aluminum-scandium (Al—Sc) alloy.

The first metal layer 180 and the second metal layer 190 may function as a connection wiring electrically connecting the first and second electrodes 121 and 125, respectively, of the acoustic resonator 100 according to the present embodiment on the substrate 110 and the electrodes of other acoustic resonators disposed adjacent to each other.

The first metal layer 180 penetrates the protective layer 160 and is bonded to the first electrode 121.

In addition, in the resonator 120, the first electrode 121 is formed to have a larger area than the second electrode 125, and the first metal layer 180 is formed on the periphery of the first electrode 121.

Therefore, the first metal layer 180 is disposed along the periphery of the resonator 120, and thus is disposed in a form surrounding the second electrode 125. However, it is not limited thereto.

In addition, in the present embodiment, the protective layer 160 located on the resonator 120 is disposed such that at least a portion thereof contacts the first metal layer 180 and the second metal layer 190. The first metal layer 180 and the second metal layer 190 are formed of a metal material having a high thermal conductivity and have a large volume, such that the first metal layer 180 and the second metal layer 190 have a high heat dissipation effect.

Therefore, the protective layer 160 is connected to the first metal layer 180 and the second metal layer 190, such that heat generated in the piezoelectric layer 123 may be quickly transferred to the first metal layer 180 and the second metal layer 190 via the protective layer 160.

In the present embodiment, at least a portion of the protective layer 160 is disposed below the first metal layer 180 and the second metal layer 190. Specifically, the protective layer 160 is insertedly disposed between the first metal layer 180 and the piezoelectric layer 123, and between the second metal layer 190, the second electrode 125, and the piezoelectric layer 123, respectively.

In the bulk-acoustic resonator 100 according to the present embodiment configured as described above, the insertion layer 170 may be formed of an F—SiO₂ thin film. In this case, in order to pattern the insertion layer 170 in a process for manufacturing the bulk-acoustic resonator, a photomask pattern formed on the insertion layer 170 can be formed more precisely, so that a degree of precision of the insertion layer 170 can be improved. This will be described in more detail as follows.

The insertion layer 170 of the bulk-acoustic resonator 100 according to the present embodiment may be completed by removing unnecessary portions disposed in a region corresponding to the central portion, after forming an insertion layer 170 to cover an entire surface formed by the membrane layer 150, the first electrode 121, and the etch stop portion 145.

In this case, as a method of removing the unnecessary portions described above, a photolithography method using a photoresist may be used. Therefore, the insertion layer 170 can also be elaborately formed only when a photoresist serving as a mask is elaborately formed.

There are many spaces in which hydroxyl groups can be adsorbed on a surface or inside of the SiO₂ thin film. Therefore, when an insertion layer is formed of a SiO₂ thin film, hydroxyl groups can be easily adsorbed on the surface or inside of the insertion layer 170.

Accordingly, if a process such as coating a photoresist on the SiO₂ insertion layer is performed, the photoresist may not be stably formed due to hydroxyl groups adsorbed on the SiO₂ insertion layer.

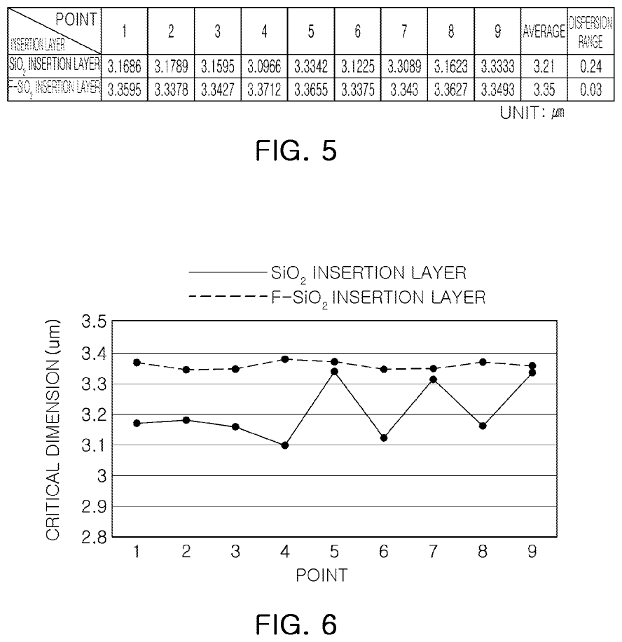

FIGS. 5 and 6 are diagrams illustrating critical dimensions of the photoresist applied on the insertion layer, FIG. 5 is a Table showing values of the critical dimensions measured at each of nine points (points 1 to 9) on the wafer, and FIG. 6 is a diagram showing the critical dimensions of FIG. 5 as a graph.

Through an experiment, when a necessary pattern is formed through an exposure/development process after applying a photoresist on the insertion layer 170 of the SiO₂ thin film, and when a photoresist is formed on the insertion layer 170 of the F—SiO₂ thin film, critical dimensions of each photoresist were measured and compared by the present applicant. As a result, it was confirmed that the critical dimension dispersion of the photoresist is significantly reduced when the insertion layer 170 was formed of an F—SiO₂ thin film and a photoresist was formed thereon.

Here, points 1 to 9 refer to nine points spaced apart in a grid shape on the wafer.

Here, the measured value of FIG. 5 is a value obtained by measuring a critical dimension (CD) of a photoresist by forming an insertion layer with a thickness of 3000 Å at a deposition temperature of 300° C. to the thickness of 3000 Å by a plasma enhanced chemical vapor deposition (CVD) (PECVD) method and then forming a photoresist thereon.

In the present embodiment, the insertion layer may be deposited through a PECVD method, but the configuration of the present disclosure is not limited thereto, and various chemical vapor deposition (CVD) methods such as low-pressure CVD (LPCVD), atmosphere pressure CVD (APCVD), or the like may be used.

The critical dimension of the photoresist can be measured using a critical dimension measurement scanning electron microscope (CD-SEM). In addition, a case in which the insertion layer is formed of silicon dioxide (SiO₂) and a case in which the insertion layer is formed of silicon dioxide (SiO₂) doped with fluorine (F) were measured, respectively.

The SiO₂ insertion layer was formed by mixing SiH₄ and O₂ in an appropriate ratio in the deposition process, and a photoresist was formed thereon to measure a critical dimension.

The SiO₂ insertion layer can be formed through Equation 1 below.

SiH₄+O₂→SiO₂+2H₂ (Equation 1)

Referring to FIGS. 5 and 6, an average of the critical dimensions of the photoresist formed on the SiO₂ insertion layer was measured to be 3.21 μm, and the dispersion range thereof was measured to be 0.24 μm.

In the F—SiO₂ insertion layer, SiH₄, O₂, and CF₄ were mixed in an appropriate ratio in the deposition process to form an insertion layer, and a photoresist was formed thereon to measure the critical dimension.

The F—SiO₂ insertion layer can be formed through Equation 2 below.

SiH₄+O₂+CF₄→F—SiO₂+2H₂+CO₂ (Equation 2)

Referring to FIGS. 5 and 6, an average of the critical dimensions of the photoresist formed on the F—SiO₂ insertion layer was measured to be 3.35 μm, and a dispersion range was measured to be 0.03 μm. Therefore, it can be seen that the dispersion range is significantly improved compared to the case in which fluorine (F) is not contained. It can be understood as a result derived as the fluorine (F) element prevents the adsorption of hydroxyl groups during the development process, since the fluorine (F) element having hydrophobic properties is disposed in the SiO₂ thin film during the deposition of the insertion layer.

Meanwhile, when the insertion layer is formed of an F—SiO₂ thin film, the surface roughness of the insertion layer may be increased.

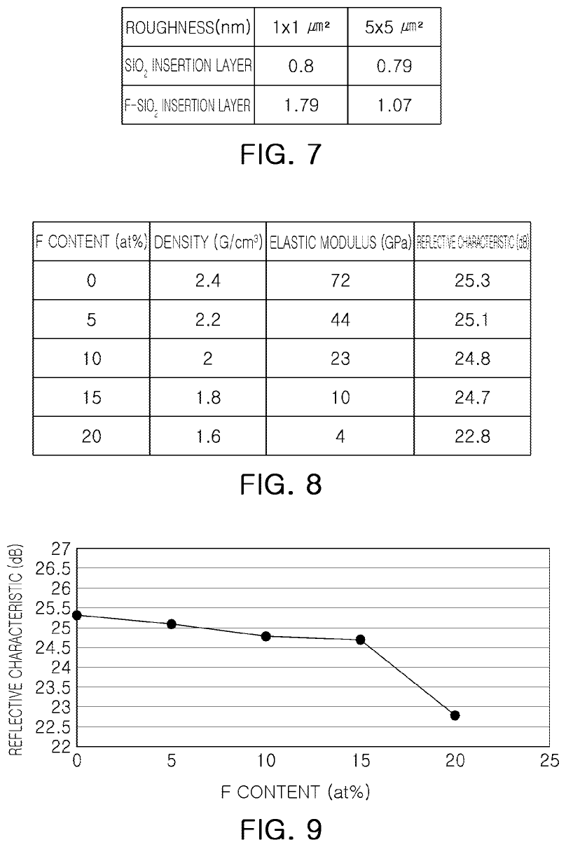

FIG. 7 is a diagram showing the result of measuring the surface roughness of the insertion layer. Referring to FIG. 7, in the case of the SiO₂ insertion layer, it was measured to have a roughness of 1 or less overall, but when the insertion layer was formed of an F—SiO₂ thin film, it was measured to have a roughness of 1 or more. Roughness was measured on 1×1 μm² and 5×5 μm² areas and the units are nm (nanometers).

When the surface roughness of the insertion layer is increased as described above, the bonding reliability between the insertion layer and the photoresist can be increased, and thus, a photoresist pattern can be formed on the surface of the insertion layer more stably.

In this embodiment, a content of fluorine (F) doped into the F—SiO₂ thin film may be 0.5 at % or more.

When the content of fluorine is 0.5 at % or more, it was confirmed that adsorption of hydroxyl groups on the surface of the insertion layer is effectively suppressed, and in addition, as shown in FIG. 7, it was confirmed that the surface roughness of the insertion layer is secured to a level capable of increasing adhesive force with the photoresist.

Therefore, in the insertion layer of the embodiment, the content of fluorine (F) doped in the F—SiO₂ thin film may be 0.5 at % or more, thereby suppressing adsorption of hydroxyl groups and at the same time, increasing bonding reliability with the photoresist.

In addition, in this embodiment, the content of fluorine (F) doped in the F—SiO₂ thin film may be 15 at % or less.

FIG. 8 is a diagram showing density, elastic modulus, and reflective characteristics of an insertion layer according to a fluorine content, and FIG. 9 is a graph showing the changes in reflective characteristics of FIG. 8.

In the present embodiment, the meaning that a reflective characteristic of the bulk-acoustic resonator is large means that a loss that occurs as a lateral wave escapes to the outside of the resonator 120 is small, and consequently, the performance of the bulk-acoustic resonator is improved.

Referring to FIG. 8, it was confirmed that as the content of fluorine (F) increased, the density of the insertion layer decreased, and thus the reflective characteristics also decreased. In addition, when the fluorine content exceeds 15 at %, it was confirmed that the reflective characteristics of the bulk-acoustic resonator rapidly deteriorate.

In addition, it was confirmed that when the fluorine content exceeded 15 at %, the surface roughness of the insertion layer may be excessively increased, and the piezoelectric layer may be abnormally grown on the inclined surface L of the insertion layer.

Therefore, in the bulk-acoustic resonator 100 of the present embodiment, an insertion layer 170 is formed of an F—SiO₂ thin film having a fluorine content of 0.5 at % or more and 15 at % or less.

Through this configuration, the bulk-acoustic resonator of the present embodiment can secure horizontal wave reflective characteristics and improve a degree of precision of the insertion layer 170.

A content analysis of each element in the F—SiO₂ thin film can be confirmed by an Energy Dispersive X-ray Spectroscopy (EDS) analysis of Scanning Electron Microscopy (SEM) and Transmission Electron Microscope (TEM), but is not limited thereto, and it is also possible to use an X-ray photoelectron spectroscopy (XPS) analysis.

In the bulk-acoustic resonator according to the present embodiment described above, since the insertion layer 170 is formed of an F—SiO₂ thin film, a degree of precision of the photoresist formed on the insertion layer 170 for patterning the insertion layer 170 may be improved.

Therefore, since the photoresist and the insertion layer 170 can be precisely and stably formed in the manufacturing process of the insertion layer 170, completeness of the bulk-acoustic resonator can be improved, and thus energy leakage of the bulk-acoustic resonator can be minimized.

The present disclosure is not limited to the above-described embodiment, and various modifications are possible.

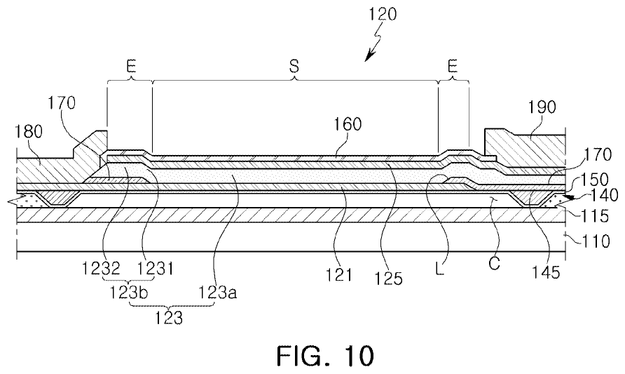

FIG. 10 is a schematic cross-sectional view of a bulk-acoustic resonator according to another embodiment of the present disclosure.

In the bulk-acoustic resonator illustrated in this embodiment, a second electrode 125 is disposed on an entire upper surface of the piezoelectric layer 123 in the resonator 120, and accordingly, the second electrode 125 is formed not only on an inclined portion 1231 of the piezoelectric layer 123 but also on an extension portion 1232 thereof.

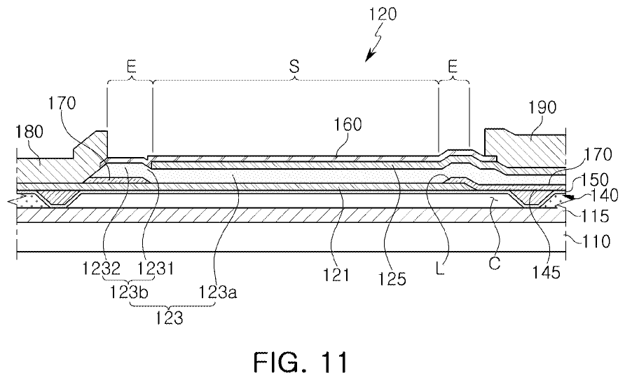

FIG. 11 is a schematic cross-sectional view of a bulk-acoustic resonator according to another embodiment of the present disclosure.

Referring to FIG. 11, in the bulk-acoustic resonator according to the present embodiment, in the cross-section of the resonator 120 cut so as to across the central portion S, an end portion of the second electrode 125 is formed only on an upper surface of a piezoelectric portion 123a of a piezoelectric layer 123, and is not formed on a bent portion 123b. Accordingly, the end of the second electrode 125 is disposed along a boundary of the piezoelectric portion 123a and the inclined portion 1231.

As described above, the bulk-acoustic resonator according to the present disclosure can be modified in various forms as necessary.

As set forth above, according to an embodiment of the present disclosure, in a bulk-wave acoustic resonator, since an insertion layer is formed of a SiO₂ thin film containing fluorine (F), a degree of precision of a photoresist formed on the insertion layer for patterning the insertion layer may be improved. Therefore, since the insertion layer can be formed in a fixed manner, energy leakage of the bulk-acoustic wave resonator may be minimized.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator, comprising:
a resonator comprising a central portion in which a first electrode, a piezoelectric layer, and a second electrode are sequentially stacked on a substrate, and an extension portion disposed along a periphery of the central portion, and in which an insertion layer is disposed below the piezoelectric layer,
wherein the insertion layer comprises a SiO₂ thin film injected with fluorine (F).

2. The bulk-acoustic wave resonator of claim 1, wherein the fluorine (F) contained in the insertion layer is contained in a range of 0.5 at % or more and 15 at % or less.

3. The bulk-acoustic wave resonator of claim 1, wherein the piezoelectric layer comprises aluminum nitride (AlN) or scandium (Sc) doped aluminum nitride.

4. The bulk-acoustic wave resonator of claim 1, wherein the first electrode comprises molybdenum (Mo).

5. The bulk-acoustic wave resonator of claim 1, wherein the insertion layer comprises an inclined surface whose thickness increases as a distance from the central portion increases, and
the piezoelectric layer comprises an inclined portion disposed on the inclined surface.

6. The bulk-acoustic wave resonator of claim 5, wherein, in a cross-section of the resonator, an end of the second electrode is disposed at a boundary between the central portion and the extension portion, or disposed on the inclined portion.

7. The bulk-acoustic wave resonator of claim 5, wherein the piezoelectric layer comprises a piezoelectric portion disposed in the central portion, and an extension portion extending outwardly of the inclined portion, and
at least a portion of the second electrode is disposed on the extension portion of the piezoelectric layer.

8. A method for manufacturing a bulk-acoustic wave resonator, comprising:
forming a resonator comprising a central portion in which a first electrode, a piezoelectric layer, and a second electrode are sequentially stacked on a substrate, and an extension portion in which an insertion layer is disposed along a periphery of the central portion,
wherein the insertion layer is disposed below the first electrode or between the first electrode and the piezoelectric layer, and is formed of a SiO₂ thin film injected with fluorine (F).

9. The method of claim 8, wherein the fluorine (F) contained in the insertion layer is contained in a range of 0.5 at % or more and 15 at % or less.

10. The method of claim 9, wherein the piezoelectric layer is formed of aluminum nitride (AlN) or scandium (Sc) doped aluminum nitride.

11. The method of claim 8, wherein the insertion layer is formed by mixing SiH₄ gas with any one of CF₄, NF₃, SiF₆, CHF₃, C₄F₈, and C₂F₆ gas.

12. The method of claim 11, wherein the insertion layer is formed by a chemical vapor deposition (CVD) method, and according to Equation 1 below,
SiH₄+O₂+CF₄→F—SiO₂+2H₂+CO₂ (Equation 1)
where F—SiO₂ is SiO₂ thin film injected with fluorine (F).

13. The method of claim 8, wherein the piezoelectric layer and the second electrode are at least partially raised by the insertion layer.

14. The method of claim 13, wherein, in a cross-section of the resonator, at least a portion of an end of the second electrode is disposed to overlap the insertion layer.

15. The method of claim 13, wherein, in a cross-section of the resonator, the end of the second electrode is disposed in the extension portion.
